(19) United States
(12) Patent Application Publication
(10) Pub. No.: US 2023/0299077 A1
(43) Pub. Date: Sep. 21, 2023

(54) SEMICONDUCTOR DEVICE

(71) Applicant: FUJI ELECTRIC CO., LTD., Kanagawa (JP)

(72) Inventors: Toru MURAMATSU, Matsumoto-city (JP); Tatsuya NAITO, Matsumoto-city (JP)

(21) Appl. No.: 18/158,439

(22) Filed: Jan. 23, 2023

(30) Foreign Application Priority Data
Mar. 15, 2022 (JP) 2022-040102

(51) Int. Cl. H01L 27/06; H01L 29/32; H01L 29/861; H01L 29/739

(52) U.S. Cl. CPC H01L 27/0664; H01L 29/32; H01L 29/8613; H01L 29/7397

(57) ABSTRACT

A semiconductor device includes a semiconductor substrate that has a transistor portion and a diode portion and that is provided with a plurality of trench portions, in which the transistor portion has a main region that has the emitter region and the contact region at the front surface of the semiconductor substrate and that is spaced apart from the diode portion and a first boundary region that is provided between the main region and the diode portion and that has, at the front surface of the semiconductor substrate, the emitter region and the base region which are alternately provided in a trench extension direction.

The contents of the following Japanese patent application(s) are incorporated herein by reference:

NO. 2022-040102 filed in JP on Mar. 15, 2022

### BACKGROUND

### 1. Technical Field

The present invention relates to a semiconductor device.

### 2. Related Art

Patent Document 1 discloses that in an RC-IGBT, between an IGBT region and a diode region, a boundary region is provided to have a lower ratio of formation of a high concentration P type layer than the IGBT region to inhibit a hole injection from an IGBT region side to a diode region side during reverse recovery.

### PRIOR ART DOCUMENT

### Patent Document

Patent Document 1
Japanese Patent Application Publication No. 2018-73911

### BRIEF DESCRIPTION OF THE DRAWINGS

FIG. 1A shows an example of a top plan view of a semiconductor device 100 according to example embodiment 1.

FIG. 1B is a figure showing an example of a cross section a-a′ in FIG. 1A.

FIG. 1C is a figure showing an example of a cross section b-b′ in FIG. 1A.

FIG. 1D shows an example of a bottom plan view of the semiconductor device 100.

FIG. 1E shows another example of the bottom plan view of the semiconductor device 100.

FIG. 2 shows an example of a top plan view of a semiconductor device 1100 according to a comparison example.

FIG. 3A is a figure showing a modification example of the cross section a-a′ in FIG. 1A.

FIG. 3B is a figure showing a modification example of the cross section b-b′ in FIG. 1A.

FIG. 4 is a figure showing a modification example of the cross section b-b′ in FIG. 1A.

FIG. 5 shows an example of a top plan view of a semiconductor device 200 according to example embodiment 2.

FIG. 6A shows an example of a top plan view of a semiconductor device 300 according to example embodiment 3.

FIG. 6B is a figure showing an example of a cross section d-d′ in FIG. 6A.

FIG. 6C is a figure showing an example of a cross section e-e′ in FIG. 6A.

FIG. 7A is a figure showing a modification example of the cross section d-d′ in FIG. 6A.

FIG. 7B is a figure showing a modification example of the cross section e-e′ in FIG. 6A.

FIG. 8A is a figure showing a modification example of the cross section d-d′ in FIG. 6A.

FIG. 8B is a figure showing a modification example of the cross section e-e′ in FIG. 6A.

FIG. 9 shows an example of a top plan view of a semiconductor device 400 according to example embodiment 4.

### DESCRIPTION OF EXEMPLARY EMBODIMENTS

Hereinafter, (some) embodiment(s) of the present invention will be described. The embodiment(s) do(es) not limit the invention according to the claims. In addition, not all of the combinations of features described in the embodiments are essential to the solving means of the invention.

In the present specification, one side in a direction parallel to a depth direction of a semiconductor substrate is referred to as an “upper” side, and the other side is referred to as a “lower” side. One surface of two principal surfaces of a substrate, a layer, or another member is referred to as an upper surface, and the other surface is referred to as a lower surface. “Upper”, “lower”, “front”, and “back” directions are not limited to a direction of gravity, or a direction of attachment to a substrate or the like when a semiconductor device is mounted.

In the present specification, technical matters may be described by using orthogonal coordinate axes of an X axis, a Y axis, and a Z axis. In the present specification, a plane parallel to a front surface of the semiconductor substrate is referred to as an XY plane, and a depth direction of the semiconductor substrate is referred to as the Z axis. It should be noted that in the present specification, a case where the semiconductor substrate is viewed in a Z axis direction is referred to as a top view.

In each example embodiment, a first conductivity type is exemplified as an N type, and a second conductivity type is exemplified as a P type; however, the first conductivity type may be the P type, and the second conductivity type may be the N type. In this case, conductivity types of the substrate, the layer, a region, and the like in each example embodiment respectively have opposite polarities.

In the present specification, in a layer or a region specified with N or P, electrons or holes are meant to be majority carriers, respectively. In addition, each of a symbol “+” and a symbol “−” added to N or P represents a layer or a region of a higher doping concentration and a lower doping concentration than that of a layer or a region without the symbol, and a symbol “++” represents a higher doping concentration than “+” while a symbol “−−” represents a lower doping concentration than “−”.

In the present specification, a doping concentration refers to a concentration of a donor or a dopant that has turned into an acceptor. Accordingly, a unit thereof is/cm³. In the present specification, a difference in concentration (that is, a net doping concentration) between the donor and the acceptor may be set as the doping concentration. In this case, the doping concentration can be measured in an SRP method. In addition, a chemical concentration of the donor and the acceptor may also be set as the doping concentration. In this case, the doping concentration can be measured by a SIMS method. If not particularly limited, any of the above may be used as the doping concentration. If not particularly limited, a peak value of a doping concentration distribution in a doping region may be set as the doping concentration in the doping region.

In addition, in the present specification, a dose amount refers to the number of ions implanted into a wafer per unit area when the ions are implanted. Accordingly, a unit thereof is /cm². It should be noted that a dose amount of a semiconductor region can be set as an integrated concentration obtained by integrating doping concentrations over the depth direction of the semiconductor region. A unit of the integrated concentration is/cm². Accordingly, the dose amount and the integrated concentration may be treated as the same. The integrated concentration may also be an integral value up to a half-value width, and in a case of being overlapped by a spectrum of another semiconductor region, the integrated concentration may be derived without an influence of the other semiconductor region.

Therefore, in the present specification, a level of the doping concentration can be read as a level of the dose amount. That is, when the doping concentration of one region is higher than the doping concentration of another region, it can be understood that the dose amount of the one region is higher than the dose amount of the other region.

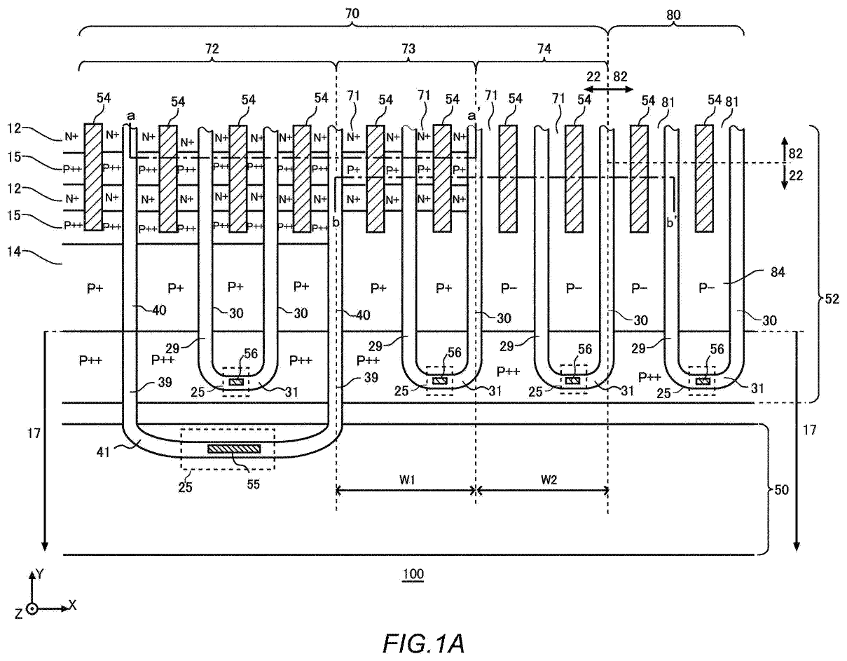

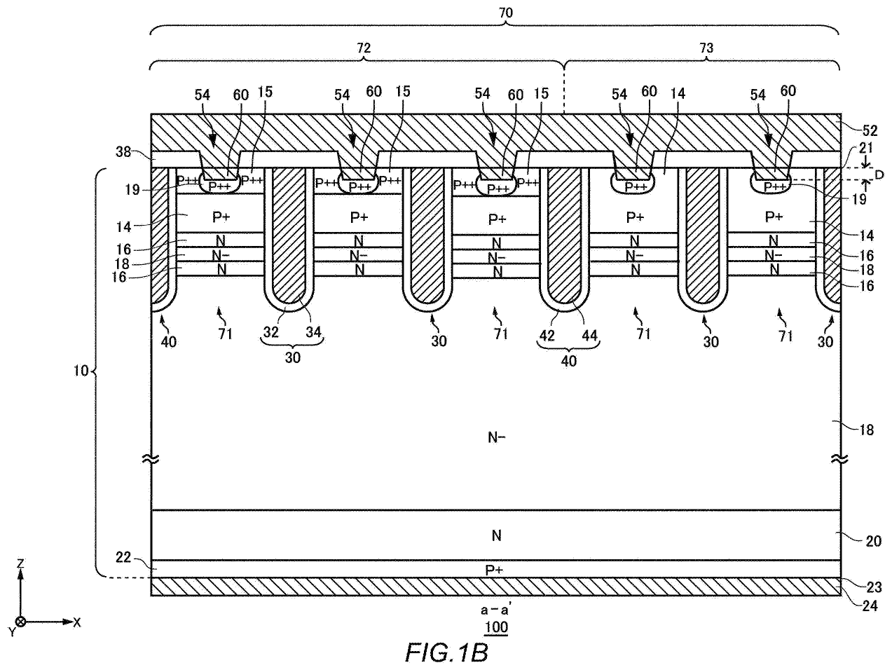

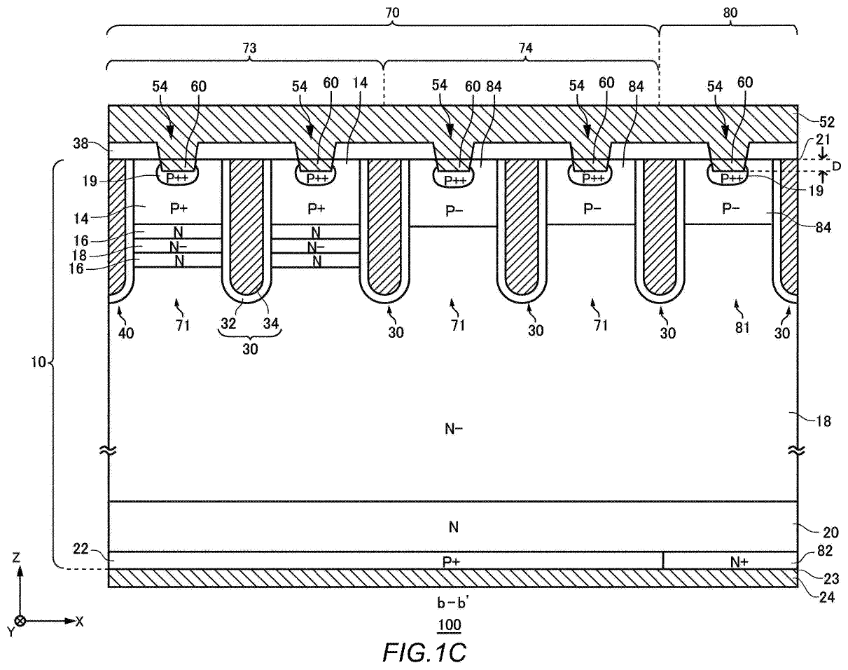

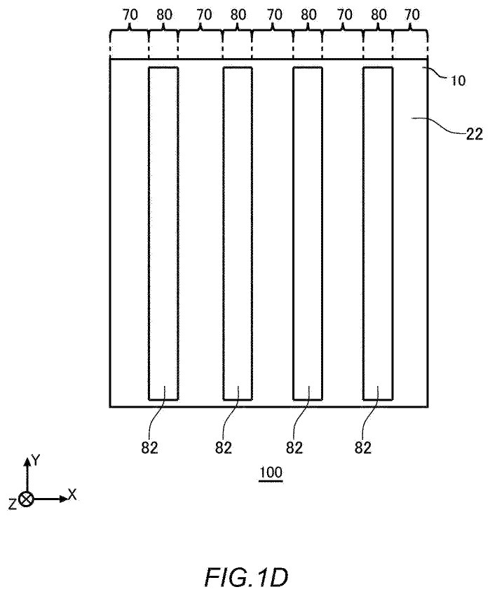

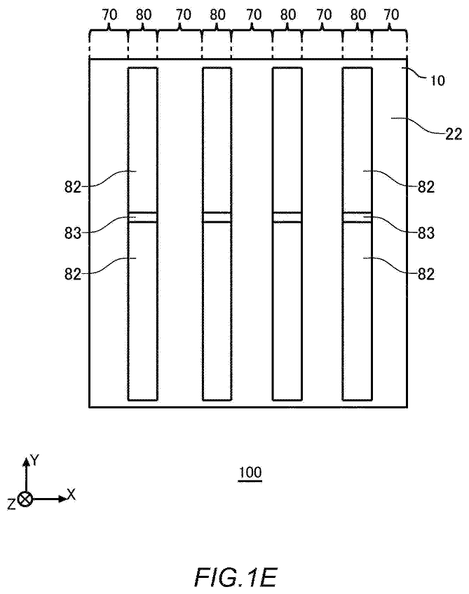

FIG. 1A shows an example of a top plan view of a semiconductor device 100 according to example embodiment 1. The semiconductor device 100 includes a semiconductor substrate having a transistor portion 70 including a transistor element such as an IGBT, and a diode portion 80 including a diode element such as a freewheeling diode (FWD). For example, the semiconductor device 100 is a reverse conducting IGBT (RC-IGBT: Reverse Conducting IGBT).

It should be noted that when simply referred to herein as a top view, it means viewing from a front surface side of the semiconductor substrate. In the present example, in the top view, an array direction of the transistor portion 70 and the diode portion 80 is referred to as the X axis, a direction perpendicular to the X axis on the front surface of the semiconductor substrate is referred to as the Y axis, and a direction perpendicular to the front surface of the semiconductor substrate is referred to as the Z axis.

Each of the transistor portion 70 and the diode portion 80 may have a longitudinal length in an extension direction. That is, the length of the transistor portion 70 in a Y axis direction is larger than a width in an X axis direction. Similarly, the length of the diode portion 80 in the Y axis direction is larger than a width in the X axis direction. The extension directions of the transistor portion 70 and the diode portion 80, and a longitudinal direction of each trench portion that will be described below may be the same.

The transistor portion 70 is a region where a collector region 22 provided on a back surface side of the semiconductor substrate is projected onto a front surface of a semiconductor substrate 10. The collector region 22 of the present example is of a P+ type, as an example. The transistor portion 70 includes a transistor such as the IGBT.

In the transistor portion 70, an emitter region 12 of the N type, a base region 14 of the P type, and a gate trench portion 40 having a gate conductive portion and a gate dielectric film are arranged at regular intervals, in the front surface side of the semiconductor substrate.

The diode portion 80 is a region where a cathode region 82 provided on the back surface side of the semiconductor substrate 10 is projected onto the front surface of the semiconductor substrate 10. The cathode region 82 of the present example is of an N+ type, as an example. The diode portion 80 includes a diode such as a freewheeling diode (FWD: Free Wheel Diode) provided to be adjacent to the transistor portion 70 at the front surface of the semiconductor substrate 10. The back surface of the semiconductor substrate 10 may be provided with a collector region of the P+ type in a region other than the cathode region.

The semiconductor substrate may be a silicon substrate, a silicon carbide substrate, or a nitride semiconductor substrate or the like of gallium nitride or the like. The semiconductor substrate in the present example is a silicon substrate.

The semiconductor device 100 of the present example includes the gate trench portion 40, a dummy trench portion 30, the emitter region 12, the base region 14, a contact region 15, a well region 17, and an anode region 84 that are provided in the front surface side of the semiconductor substrate. Each of the gate trench portion 40 and the dummy trench portion 30 is an example of the trench portion.

The semiconductor device 100 of the present example also includes a gate metal layer 50 and an emitter electrode 52 that are provided above the front surface of the semiconductor substrate. An interlayer dielectric film is provided between the emitter electrode 52 and the gate metal layer 50, and the front surface of the semiconductor substrate, although it is omitted in FIG. 1A. The interlayer dielectric film of the present example is provided with contact holes 54, 55, and 56 that penetrate through the interlayer dielectric film. In FIG. 1A, each contact hole is hatched with oblique lines.

The emitter electrode 52 is provided above the gate trench portion 40, the dummy trench portion 30, the emitter region 12, the base region 14, the contact region 15, the well region 17, and the anode region 84. The emitter electrode 52 is electrically connected, through the contact hole 54, to the emitter region 12, the base region 14, the contact region 15, and the anode region 84 at the front surface of the semiconductor substrate.

The emitter electrode 52 and the gate metal layer 50 are formed of a material containing metal. At least a part of a region of the emitter electrode 52 may be formed of aluminum, or an alloy (for example, an aluminum-silicon alloy, an aluminum-silicon-copper alloy, or the like) which contains aluminum as a main component. At least a part of a region of the gate metal layer 50 may be formed of aluminum, or an alloy (for example, an aluminum-silicon alloy, an aluminum-silicon-copper alloy, or the like) which contains aluminum as a main component.

The emitter electrode 52 and the gate metal layer 50 may have a barrier metal formed of titanium, a titanium compound, or the like under a region formed of aluminum and the like. The emitter electrode 52 and the gate metal layer 50 are provided separately from each other.

The contact hole 55 connects the gate conductive portion in the gate trench portion 40 in the transistor portion 70, and the gate metal layer 50. In the contact hole 55, a plug formed of tungsten or the like may be provided via the barrier metal.

The contact hole 56 connects dummy conductive portions in the dummy trench portions 30 provided in the transistor portion 70 and the diode portion 80, and the emitter electrode 52. In the contact hole 56, a plug formed of tungsten or the like may be provided via the barrier metal.

A connection portion 25 electrically connects a front surface side electrode such as the emitter electrode 52 or the gate metal layer 50, and the semiconductor substrate. In an example, the connection portion 25 is provided in a region including an interior of the contact hole 55, between the gate metal layer 50 and the gate conductive portion. The connection portion 25 is also provided in a region including an interior of the contact hole 56, between the emitter electrode 52 and a dummy conductive portion.

The connection portion 25 is formed of a conductive material including metal such as tungsten, and polysilicon doped with impurities, or the like. In addition, the connection portion 25 may also have the barrier metal of titanium nitride or the like. Here, the connection portion 25 is formed of polysilicon (N+) doped with impurities of the N type. The connection portion 25 is provided above the front surface of the semiconductor substrate via a dielectric film such as an oxide film, or the like.

The gate trench portion 40 is arrayed at a predetermined interval along a predetermined array direction (the X axis direction in the present example). The gate trench portion 40 of the present example may have: two extension parts 39 that extend along the extension direction (the Y axis direction in the present example) which is parallel to the front surface of the semiconductor substrate and is perpendicular to the array direction; and a connection part 41 that connects the two extension parts 39.

It is preferable that at least a part of the connection part 41 is formed in a curved shape. By connecting end portions of the two extension parts 39 of the gate trench portion 40, electric field concentrations at the end portions of the extension parts 39 can be relaxed. At the connection part 41 of the gate trench portion 40, the gate metal layer 50 may be connected to the gate conductive portion.

The dummy trench portion 30 is a trench portion in which the dummy conductive portion is provided to be electrically connected to the emitter electrode 52. The dummy trench portion 30 is arrayed, similarly to the gate trench portion 40, at a predetermined interval along a predetermined array direction (the X axis direction in the present example). The dummy trench portion 30 of the present example may have, similarly to the gate trench portion 40, a U shape at the front surface of the semiconductor substrate. That is, the dummy trench portion 30 may have two extension parts 29 that extend along the extension direction, and a connection part 31 that connects the two extension parts 29.

The transistor portion 70 of the present example has a structure in which one gate trench portion 40 and two dummy trench portions 30 are repeatedly arrayed. That is, the transistor portion 70 of the present example has the gate trench portion 40 and the dummy trench portion 30 at a ratio of 1:2. For example, in the transistor portion 70, two extension parts 29 are provided between the extension parts 39 adjacent to each other in the array direction.

Note that the ratio of the gate trench portion 40 and the dummy trench portion 30 is not limited to that of the present example. The ratio of the gate trench portion 40 and the dummy trench portion 30 may be 1:1, or may be 2:3. In addition, the transistor portion 70 may have a so-called full gate structure in which the dummy trench portion 30 is not provided and the gate trench portion 40 is entirely provided.

The well region 17 is provided to be closer to the front surface side of the semiconductor substrate than the drift region 18 which will be described below. The well region 17 is an example of a well region provided at an edge side of the semiconductor device 100. The well region 17 is of a P++ type as an example. The well region 17 is provided in a predetermined range from an end portion of an active region on a side in which the gate metal layer 50 is provided.

A diffusion depth of the well region 17 may be deeper than depths of the gate trench portion 40 and the dummy trench portion 30. Partial regions of the gate trench portion 40 and the dummy trench portion 30 on a gate metal layer 50 side are provided in the well region 17. Bottoms of ends of the gate trench portion 40 and the dummy trench portion 30 in the extension direction may be covered with the well region 17.

The contact hole 54 is provided above each region of the emitter region 12 and the contact region 15 in the transistor portion 70. The contact hole 54 is also provided above the anode region 84 in the diode portion 80. None of the contact holes 54 is provided above the well region 17 provided at both ends in the Y axis direction. In this way, the interlayer dielectric film is provided with one or more contact holes 54. The contact hole 54 of the present example may be provided to extend in the extension direction.

A mesa portion 71 and a mesa portion 81 are mesa portions provided adjacent to the trench portion in a plane parallel to the front surface of the semiconductor substrate. The mesa portion is a part of the semiconductor substrate interposed between two trench portions adjacent to each other, and may be a part ranging from the front surface of the semiconductor substrate to a depth of a deepest bottom portion of each trench portion. The extension part of each trench portion may be set as one trench portion. That is, a region interposed between two extension parts may be set as the mesa portion.

The mesa portion 71 is provided adjacent to at least one of the dummy trench portion 30 or the gate trench portion 40 in the transistor portion 70. The mesa portion 71 has the well region 17, the emitter region 12, the base region 14, and the contact region 15, at the front surface of the semiconductor substrate.

The base region 14 is a region provided in the front surface side of the semiconductor substrate, in the transistor portion 70. The anode region 84 is a region provided in the front surface side of the semiconductor substrate, in the diode portion 80.

The doping concentration of the anode region 84 is lower than the doping concentration of the base region 14. As an example, the base region 14 is of the P+ type, and the anode region 84 is of a P− type. The doping concentration of the anode region 84 is 2.0E12 cm⁻³ or more and 8.0E12 cm⁻³ or less, and the doping concentration of the base region 14 is 2.0E13 cm⁻³ or more and 3.0E13 cm⁻³ or less. It should be noted that the E means the power of 10, and for example, 1E16 cm⁻³ means 1×10¹⁶ cm⁻³. In the present example, by lowering the doping concentration of the anode region 84, it is possible to suppress a hole injection during reverse recovery.

The emitter region 12 is a region which is of the same conductivity type as that of the drift region 18, and which has a doping concentration higher than that of the drift region 18. The emitter region 12 of the present example is of the N+ type, as an example. An example of the dopant of the emitter region 12 is arsenic (As). The emitter region 12 is provided in contact with the gate trench portion 40 at a front surface of the mesa portion 71. The emitter region 12 may be provided to extend in the X axis direction from one trench portion to the other trench portion of two trench portions that interpose the mesa portion 71 therebetween.

In addition, the emitter region 12 may be, or may not be in contact with the dummy trench portion 30. The emitter region 12 of the present example is in contact with the dummy trench portion 30. The emitter region 12 is not provided in the mesa portion 81.

The contact region 15 is a region which is of the same conductivity type as that of the base region 14, and which has a doping concentration higher than that of the base region 14. The contact region 15 of the present example is of the P++ type as an example. The contact region 15 of the present example is provided at the front surface of the mesa portion 71. The contact region 15 may be provided in the X axis direction from one trench portion to the other trench portion of two trench portions that interpose the mesa portion 71 therebetween. The contact region 15 may be, or may not be in contact with the gate trench portion 40. In addition, the contact region 15 may be, or may not be in contact with the dummy trench portion 30. In the present example, the contact region 15 is in contact with the dummy trench portion 30 and the gate trench portion 40.

The transistor portion 70 of the present example has a main region 72 spaced apart from the diode portion 80, a first boundary region 73 provided between the main region 72 and the diode portion, and a second boundary region 74 provided between the first boundary region 73 and the diode portion 80.

In the mesa portion 71 of the main region 72, the emitter region 12 and the contact region 15 are alternately provided in the extension direction at the front surface of the semiconductor substrate. In the mesa portion 71 of the first boundary region 73, the emitter region 12 and the base region 14 are alternately provided in the extension direction at the front surface of the semiconductor substrate. In the mesa portion 71 of the second boundary region 74, the anode region 84 is provided at the front surface of the semiconductor substrate. In the mesa portion 71 of the second boundary region 74, the emitter region 12 and the contact region 15 are not provided.

The mesa portion 81 is provided in a region interposed between the dummy trench portions 30 adjacent to each other in the diode portion 80. In the mesa portion 81 of the present example, the anode region 84 is provided at the front surface of the semiconductor substrate. That is, in the present example, a front surface structure of the second boundary region 74 and a front surface structure of the diode portion 80 are common.

In this way, in the present example, the first boundary region 73 and the second boundary region 74 are provided between the main region 72 operating as the transistor, and the diode portion 80. By providing the anode region 84 having a low doping concentration in the second boundary region 74, it is possible to suppress the hole injection during the reverse recovery.

On the other hand, it is possible to increase an area of the active region in addition to the main region 72 by providing the emitter region 12, while the hole injection during the reverse recovery is suppressed by providing the base region 14 having a lower doping concentration than that of the contact region 15, in the first boundary region 73. As an example, when a length of the first boundary region 73 is set as W1, and a length of the second boundary region 74 is set as W2 in the array direction, a total length W1+W2 of the first boundary region 73 and the second boundary region 74 is 68 μm to 72 μm, and the length W1 of the first boundary region 73 is 34 μm to 36 μm.

FIG. 1B is a figure showing an example of a cross section a-a′ in FIG. 1A. FIG. 1C is a figure showing an example of a cross section b-b′ in FIG. 1A. The cross section a-a′ and the cross section b-b′ are XZ plane passing through the contact region 15. The cross section a-a′ mainly shows the XZ plane from the main region 72 to the first boundary region 73, and the cross section b-b′ mainly shows the XZ plane from the first boundary region 73 to the diode portion 80.

The semiconductor device 100 of the present example has the semiconductor substrate 10, an interlayer dielectric film 38, the emitter electrode 52, and a collector electrode 24, in the cross section a-a′ and the cross section b-b′. The emitter electrode 52 is provided above the semiconductor substrate 10 and the interlayer dielectric film 38.

The drift region 18 is a region provided in the semiconductor substrate 10. The drift region 18 of the present example is of an N− type, as an example. The drift region 18 may be a remaining region in which another doping region is not formed in the semiconductor substrate 10. That is, the doping concentration of the drift region 18 may be the doping concentration of the semiconductor substrate 10.

The buffer region 20 is a region provided below the drift region 18. The buffer region 20 of the present example may be of the same conductivity type as that of the drift region 18, and is of the N type as an example. The doping concentration of the buffer region 20 is higher than the doping concentration of the drift region 18. The buffer region 20 may function as a field stop layer which prevents a depletion layer expanding from a lower surface side of the base region 14, from reaching the collector region 22 and the cathode region 82.

The collector region 22 is a region which is provided below the buffer region 20 in the transistor portion 70, and which is of a conductivity type different from that of the drift region 18. The cathode region 82 is a region provided below the buffer region 20 in the diode portion 80 and of the same conductivity type as that of the drift region 18. A boundary between the collector region 22 and the cathode region 82 is a boundary between the transistor portion 70 and the diode portion 80.

The collector electrode 24 is provided on a back surface 23 of the semiconductor substrate 10. The collector electrode 24 is formed of a conductive material such as metal, or by stacking conductive materials.

The base region 14 is a region which is provided above the drift region 18 in the mesa portion 71 of the main region 72 and the first boundary region 73, and which is of a conductivity type different from that of the drift region 18. The base region 14 of the present example is of the P+ type as an example. The base region 14 is provided in contact with the gate trench portion 40. The base region 14 may be provided in contact with the dummy trench portion 30.

The anode region 84 is a region which is provided above the drift region 18 in the mesa portion 71 of the second boundary region 74 and the mesa portion 81 of the diode portion 80, and which is of a conductivity type different from that of the drift region 18. The anode region 84 of the present example is of the P− type as an example. The anode region 84 is provided in contact with the dummy trench portion 30.

The emitter region 12 is provided between the base region 14 and the front surface 21. The emitter region 12 of the present example is provided in the mesa portion 71 of the main region 72 and the first boundary region 73, and is not provided in the mesa portion 71 of the second boundary region 74 and the mesa portion 81. The emitter region 12 is provided in contact with the gate trench portion 40. The emitter region 12 may be, or may not be in contact with the dummy trench portion 30.

When the diode portion 80 is brought into conduction, an electron current flows from the cathode region 82 to the anode region 84. When the electron current reaches the anode region 84, conductivity modulation occurs, and a hole current flows from the anode region 84. In addition, the electron current diffused from the cathode region 82 facilitates the hole injection from the contact region 15 of the transistor portion 70, thereby increasing a hole density in the semiconductor substrate 10. Thereby, it takes long in time for the hole to annihilate when the diode portion 80 is turned off, and thus a reverse recovery peak current becomes large and a reverse recovery loss becomes large.

As a technique for suppressing such a hole current, a technique in which a lifetime control region that includes a lifetime killer is provided in the front surface side of the semiconductor substrate, is known. As an example, the lifetime killer is an electron beam which is injected into the entire semiconductor substrate, helium implanted to a predetermined depth, the electron beam, a proton, or the like, and the lifetime control region is a crystal defect formed inside the semiconductor substrate by implanting the lifetime killer. The lifetime control region facilitates recombination annihilation of the electron and the hole which occurs when the diode portion is brought into conduction, and reduces the reverse recovery loss.

In the present example, the lifetime control region including the lifetime killer is not provided in a front surface 21 side of the semiconductor substrate 10. In the present example, by lowering the doping concentration of the anode region 84, it is possible to suppress the hole injection during the reverse recovery even though the lifetime control region is not provided.

A trench contact portion 60 electrically connects the emitter electrode 52 and the semiconductor substrate. The trench contact portion 60 is provided continuously from the contact hole 54. The trench contact portion 60 of the present example is provided in each of the mesa portion 71 and the mesa portion 81.

The trench contact portion 60 contains a conductive material with which the contact hole 54 is filled. The trench contact portion 60 is provided between two trench portions adjacent to each other among a plurality of trench portions. A bottom portion of the trench contact portion 60 of the present example is covered with a plug region 19. It should be noted that the bottom portion of the trench contact portion 60 is a lower end of the trench contact portion 60, and a part of a side wall that is connected to the lower end. The trench contact portion 60 may contain the same material as that of the emitter electrode 52.

It should be noted that in the trench contact portion 60 and the contact hole 54, the barrier metal formed of titanium, a titanium compound, or the like may be provided. Further, in the trench contact portion 60 and the contact hole 54, the plug formed of tungsten or the like may be provided via the barrier metal.

The lower end of the trench contact portion 60 is shallower than a lower end of the emitter region 12. By providing the trench contact portion 60, a resistance in the base region 14 is reduced, and thus it becomes easy to extract a minority carrier (for example, the hole). Thereby, even when the base region 14 that has a doping concentration lower than that of the contact region 15 is provided in the first boundary region 73, it is possible to enhance a destructive breakdown withstand capability such as a latch-up withstand capability due to the minority carrier.

As an example, a distance between the lower end of the emitter region 12 and the front surface 21 is 0.4 μm to 0.5 μm, and a distance D between the lower end of the trench contact portion 60 and the front surface 21 is 0.3 μm to 0.4 μm.

It should be noted that the lower end of the trench contact portion 60 may be shallower than the lower end of the emitter region 12, or may have the same depth as the lower end of the emitter region 12. As an example, a distance between the lower end of the emitter region 12 and the front surface 21 is 0.4 μm to 0.5 μm, and the distance D between the lower end of the trench contact portion 60 and the front surface 21 is 0.3 μm to 0.5 μm.

For example, the trench contact portion 60 is formed by etching the interlayer dielectric film 38. The trench contact portion 60 has a bottom surface having a substantially planar shape. The trench contact portion 60 of the present example has a tapered shape in which the side wall is inclined. Note that the side wall of the trench contact portion 60 may be provided to be substantially perpendicular to the front surface 21.

The plug region 19 is provided at the bottom portion of trench contact portion 60 in each of the mesa portion 71 and the mesa portion 81. The plug region 19 is a region which is of the same conductivity type as those of the base region 14 and the anode region 84, and which has a higher doping concentration than those of the base region 14 and the anode region 84. The plug region 19 of the present example is of the P++ type, as an example.

For example, the plug region 19 is formed by implanting an ion of boron (B) or boron fluoride (BF₂) from the lower end of the trench contact portion 60. The plug region 19 may have the same doping concentration as that of the contact region 15. The doping concentration of the plug region 19 of the present example is 1E15 cm⁻³ or more and 1E16 cm⁻³ or less. The plug region 19 suppresses a latch-up by extracting the minority carrier.

The plug region 19 is diffused from the lower end of the trench contact portion 60 and covers at least a part of the side wall of the trench contact portion 60. A lower end of the plug region 19 may have the same depth as that of a lower end of the contact region 15, or may be shallower than that of the lower end of the contact region 15. This suppresses an influence on a gate threshold by the plug region 19 contributing to the base region 14.

In addition, in the present example, by providing the plug region 19 in the diode portion 80 as well, it is possible to compensate for a low doping concentration in the anode region 84, and to secure an ohmic contact.

An accumulation region 16 is a region provided below the main region 72 and the first boundary region 73. As shown in FIG. 1B, the accumulation region 16 of two or more stages may be provided in the drift region 18. The accumulation region 16 of the present example is of the same conductivity type as that of the drift region 18, and is of the N type, as an example. The accumulation region 16 may not be provided below the anode region 84, that is, in the second boundary region 74 and the diode portion 80.

In addition, the accumulation region 16 is provided in contact with the gate trench portion 40. The accumulation region 16 may be, or may not be in contact with the dummy trench portion 30. The doping concentration of the accumulation region 16 is higher than the doping concentration of the drift region 18. The doping concentration of the accumulation region 16 may be 1E12 cm⁻³ or more and 1E14 cm⁻³ or less. Providing the accumulation region 16 makes it possible to enhance a carrier injection enhancement effect (IE effect) to reduce an ON voltage of the transistor portion 70.

One or more gate trench portions 40 and one or more dummy trench portions 30 are provided at the front surface 21. Each trench portion is provided from the front surface 21 to the drift region 18. In a region where at least any of the emitter region 12, the base region 14, the contact region 15, or the accumulation region 16 is provided, each trench portion also penetrates through these regions to reach the drift region 18. A structure in which the trench portion penetrates through the doping region is not limited to a structure manufactured in order of forming the doping region and then forming the trench portion. A structure in which the trench portion is formed and then the doping region is formed between the trench portions is also included in the structure in which the trench portion penetrates through the doping region.

The gate trench portion 40 has a gate trench provided at the front surface 21, a gate dielectric film 42, and a gate conductive portion 44. The gate dielectric film 42 is provided to cover an inner wall of the gate trench. The gate dielectric film 42 may be formed by oxidizing or nitriding a semiconductor on the inner wall of the gate trench. The gate conductive portion 44 is provided on an inner side further than the gate dielectric film 42 in the gate trench. The gate dielectric film 42 insulates the gate conductive portion 44 from the semiconductor substrate 10. The gate conductive portion 44 is formed of a conductive material such as polysilicon. The gate trench portion 40 is covered with the interlayer dielectric film 38 on the front surface 21.

The gate conductive portion 44 includes a region facing the base region 14 adjacent on a mesa portion 71 side with the gate dielectric film 42 interposed therebetween in the depth direction of the semiconductor substrate 10. When a predetermined voltage is applied to the gate conductive portion 44, a channel is formed by an inversion layer of electrons on a surface layer in the base region 14 at an interface in contact with the gate trench.

The dummy trench portion 30 may have the same structure as that of the gate trench portion 40. The dummy trench portion 30 includes a dummy trench provided in the front surface 21 side, a dummy dielectric film 32, and a dummy conductive portion 34. The dummy dielectric film 32 is provided to cover an inner wall of the dummy trench. The dummy conductive portion 34 is provided inside the dummy trench, and is provided on an inner side further than the dummy dielectric film 32. The dummy dielectric film 32 insulates the dummy conductive portion 34 from the semiconductor substrate 10. The dummy trench portion 30 is covered with the interlayer dielectric film 38 at the front surface 21.

The interlayer dielectric film 38 is provided on the front surface 21. The emitter electrode 52 is provided above the interlayer dielectric film 38. The interlayer dielectric film 38 is provided with one or more contact holes 54 to electrically connect the emitter electrode 52 and the semiconductor substrate 10. Similarly, the contact hole 55 and the contact hole 56 may also be provided to penetrate through the interlayer dielectric film 38.

FIG. 1D shows an example of a bottom plan view of the semiconductor device 100. Here, only the active region is shown on the back surface 23 of the semiconductor substrate 10, and an edge region is omitted. The collector electrode 24 provided on the back surface 23 of the semiconductor substrate 10 is also omitted.

The collector region 22 is a region which is provided below the buffer region 20 in the transistor portion 70, and which is of a conductivity type different from that of the drift region 18. The cathode region 82 is a region which is provided below the buffer region 20 in the diode portion 80, and which is of the same conductivity type as that of the drift region 18. A boundary between the collector region 22 and the cathode region 82 is a boundary between the transistor portion 70 and the diode portion 80. In the extension direction, the collector region 22 may be provided between the end portion of the active region and an end portion of the cathode region 82.

FIG. 1E shows another example of the bottom plan view of the semiconductor device 100. Here, the description common to FIG. 1D is omitted. The cathode region of the present example has a first cathode region 82 of the first conductivity type corresponding to the cathode region 82 of FIG. 1D, and a second cathode region 83 that is of the second conductivity type and that has an area smaller than that of the first cathode region 82.

As an example, the second cathode region 83 is a region evenly provided in a part of the first cathode region 82. The second cathode region 83 of the present example may be provided to extend in the array direction. In the extension direction, the first cathode region 82 is longer than the second cathode region 83. The second cathode region 83 may have the same doping concentration as that of the collector region 22. The second cathode region 83 may be in contact with the collector region 22 at an end portion in the array direction. The second cathode region 83 suppresses a surge voltage during the reverse recovery, and improves a characteristic of the diode portion 80.

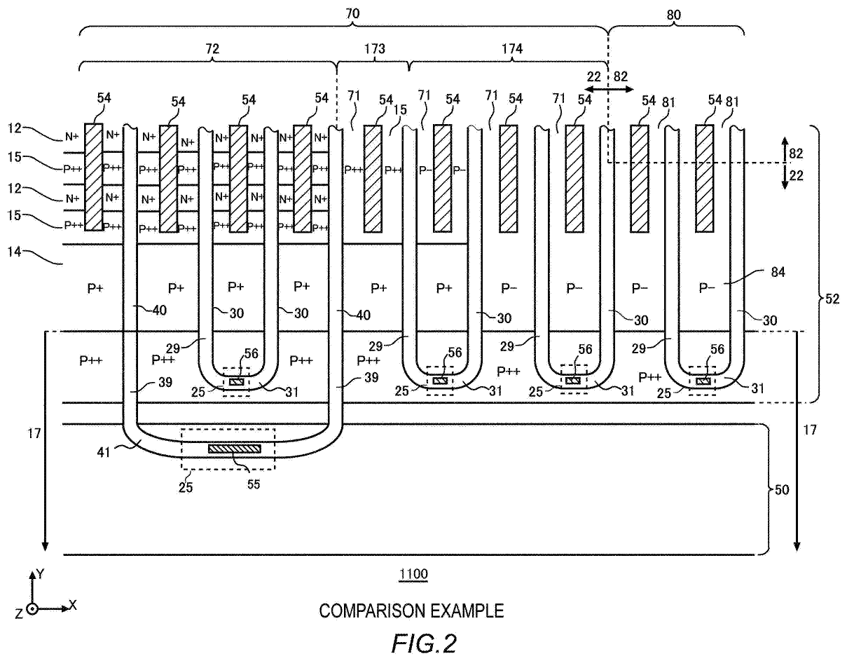

FIG. 2 shows an example of a top plan view of a semiconductor device 1100 according to a comparison example. Here, an element that is common to the semiconductor device 100 shown in FIG. 1A is given the same sign and numeral, and the description thereof will be omitted.

The semiconductor device 1100 has a first boundary region 173 and a second boundary region 174 provided between the main region 72 of the transistor portion 70 and the diode portion 80. The first boundary region 173 is a region including the mesa portion 71 closest to a main region 72 side, and extends in the extension direction in which the contact region 15 extends, at the front surface 21 of the semiconductor substrate 10. The second boundary region 174 is a region which is provided between the first boundary region 173 and the diode portion 80, and in which the anode region 84 is provided at the front surface 21 of the semiconductor substrate 10, similarly to the diode portion 80.

Similarly to the semiconductor device 100, the semiconductor device 1100 suppresses the reverse recovery loss by providing the diode portion 80 with the anode region 84 having a low doping concentration. Therefore, in the semiconductor device 1100, by providing the anode region 84 having a low doping concentration in the second boundary region 174 as well, the hole injection from the main region 72 during the reverse recovery is suppressed. In addition, by providing the contact region 15 in the first boundary region 173, the latch-up is suppressed. A total width of the first boundary region 173 and the second boundary region 174 in the array direction is approximately equal to the total width of W1+W2 of the first boundary region 73 and the second boundary region 74 in the semiconductor device 100.

However, in the semiconductor device 1100, the first boundary region 173 and the second boundary region 174 are invalid regions, and thus the area of the active region is reduced. In contrast with this, in the semiconductor device 100, it is possible to reduce an invalid region by providing the emitter region 12, while the hole injection during the reverse recovery is suppressed by providing the base region 14 having a doping concentration lower than that of the contact region 15 in the first boundary region 73.

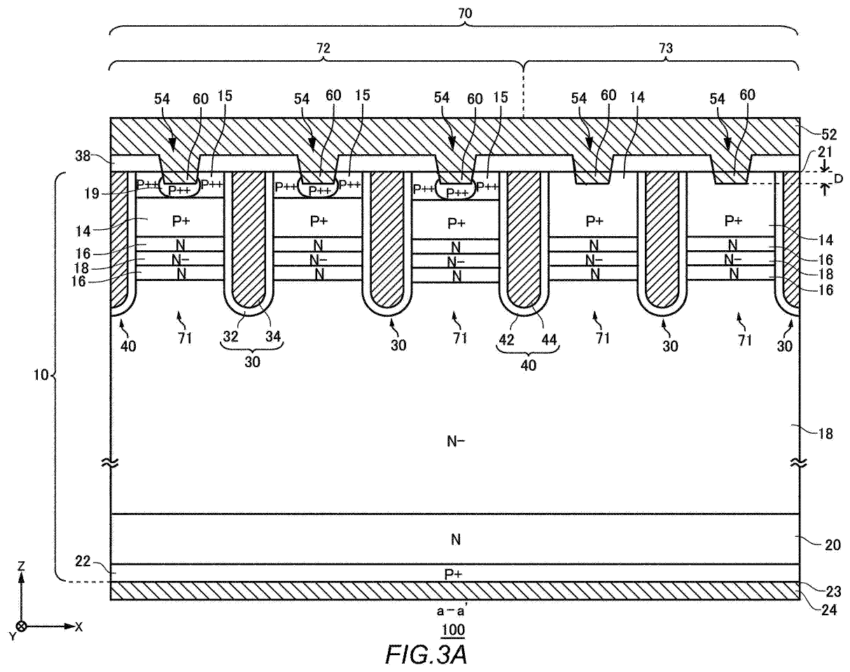

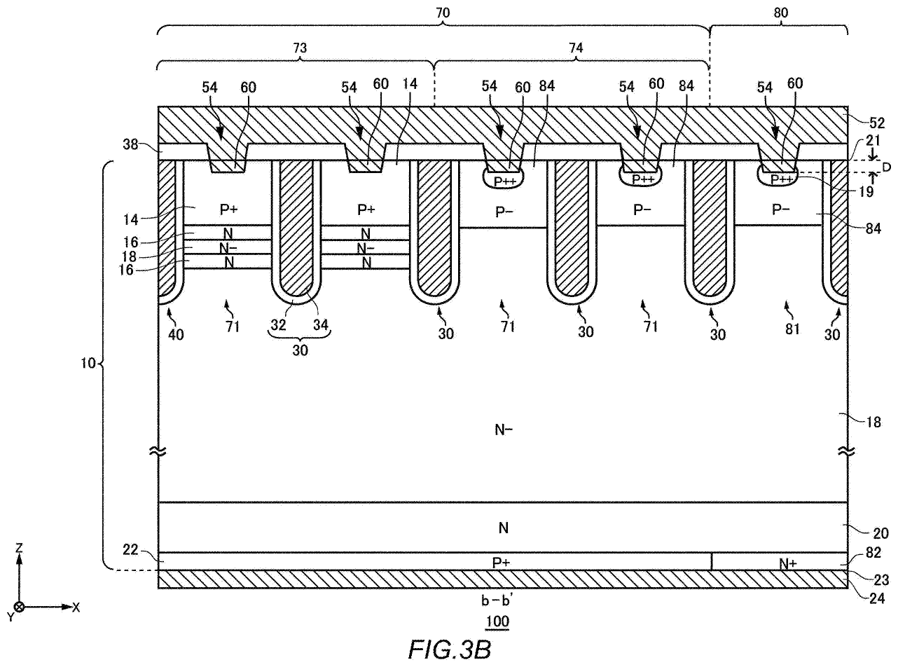

FIG. 3A is a figure showing a modification example of the cross section a-a′ in FIG. 1A. FIG. 3B is a figure showing a modification example of the cross section b-b′ in FIG. 1A. Here, an element that is common to FIG. 1B and FIG. 1C is given the same sign and numeral, and the description thereof will be omitted.

In the present modification example, the plug region 19 is not provided at the lower end of the trench contact portion 60 provided in the first boundary region 73. That is, in the first boundary region 73, the bottom portion and the side wall of the trench contact portion 60 are covered with the emitter region 12 or the base region 14.

In this way, by providing the plug region 19 in a region other than the first boundary region 73 and omitting the plug region 19 in the first boundary region 73, it is possible to further suppress the hole injection during the reverse recovery while the extraction of the hole is facilitated.

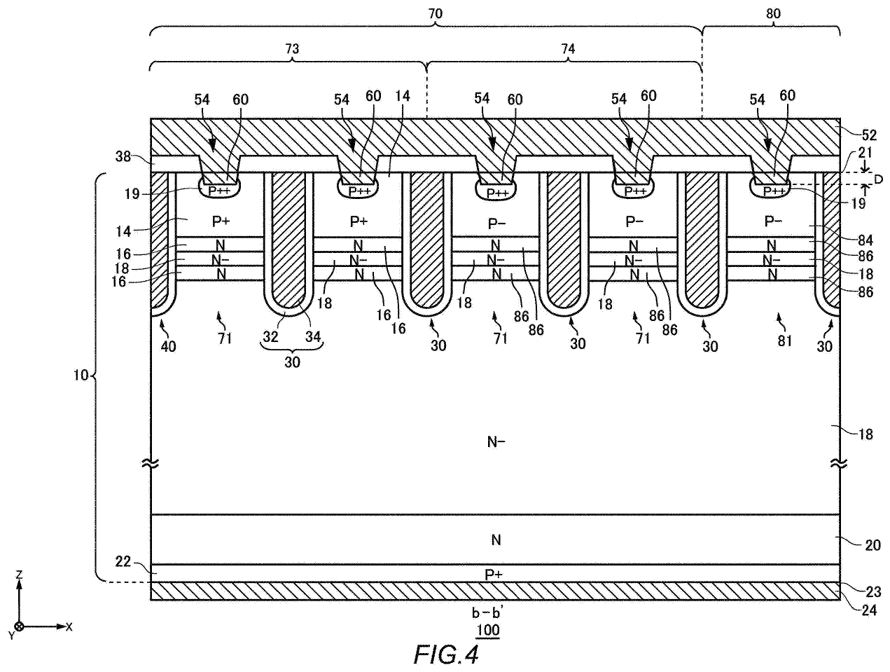

FIG. 4 is a figure showing a modification example of the cross section b-b′ in FIG. 1A. Here, an element that is common to FIG. 1C is given the same sign and numeral, and the description thereof will be omitted.

In the present modification example, an accumulation region 86 of the first conductivity type is provided below the anode region 84 in the second boundary region 74 and the diode portion 80. The accumulation region 86 of the present example is of the same conductivity type as that of the drift region 18, and is of the N type, as an example. Similarly to the accumulation region 16, the accumulation region 86 of two or more stages may be provided in the drift region 18. The doping concentration of the accumulation region 86 is lower than the doping concentration of the accumulation region 16. The doping concentration of the accumulation region 86 may be 1E11 cm⁻³ or more and 1E12 cm⁻³ or less.

In this way, by the semiconductor device 100 according to the present modification example having the accumulation region 86 that has the low doping concentration below the anode region 84, the accumulation region is entirely provided over the transistor portion 70 and the diode portion 80. In the present modification example, this makes it possible to enhance the IE effect and reduce the ON voltage of the transistor portion 70 while a balance with the anode region 84 that has a low doping concentration is maintained.

It should be noted that as shown in FIG. 3A and FIG. 3B, the accumulation region 86 may be provided in the second boundary region 74 and the diode portion 80 even when the plug region 19 is not provided in the first boundary region 73.

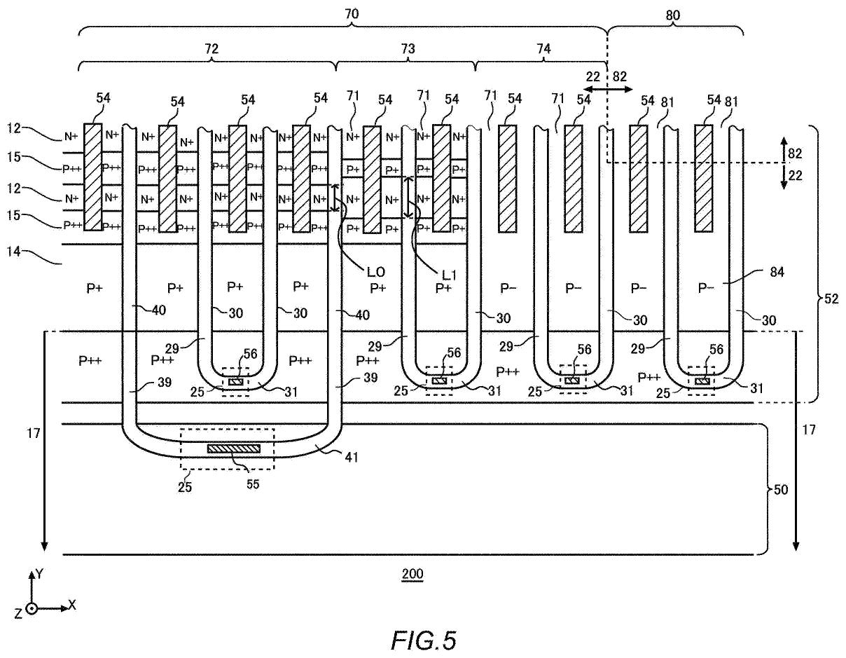

FIG. 5 shows an example of a top plan view of a semiconductor device 200 according to example embodiment 2. Here, an element that is common to FIG. 1A is given the same sign and numeral, and the description thereof will be omitted.

In the present example, in the top view of the semiconductor substrate 10, a length L0 of the emitter region 12 provided in the main region 72 in the extension direction is smaller than a length L1 of the emitter region 12 provided in the first boundary region 73 in the extension direction.

That is, in the present example, in the top view of the semiconductor substrate 10, an area ratio of the emitter region 12 in the first boundary region 73 is greater than an area ratio of the emitter region 12 in the main region 72. In addition, in the top view of the semiconductor substrate 10, an area ratio of the base region 14 in the first boundary region 73 is smaller than an area ratio of the contact region 15 in the main region 72.

In this way, in the first boundary region 73, by increasing the area ratio of the emitter region 12 and decreasing the area ratio of the base region 14, it is possible to further increase the area of the active region and to suppress the hole injection during the reverse recovery.

It should be noted that the semiconductor device 200 may not be provided with the plug region 19 in the first boundary region 73 as in FIG. 3A and FIG. 3B. In addition, the semiconductor device 200 may be provided with the accumulation region 86 in the second boundary region 74 and the diode portion 80 as in FIG. 4.

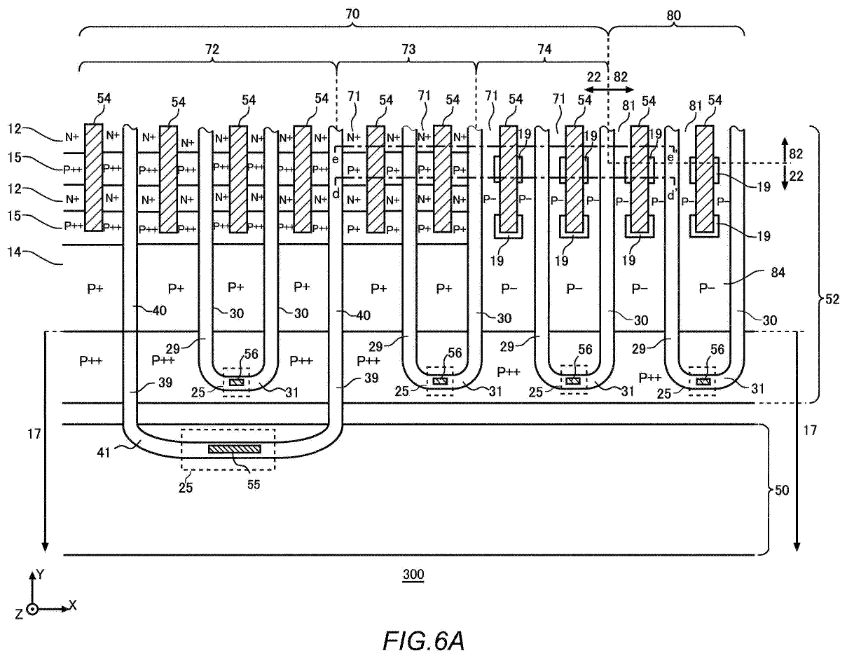

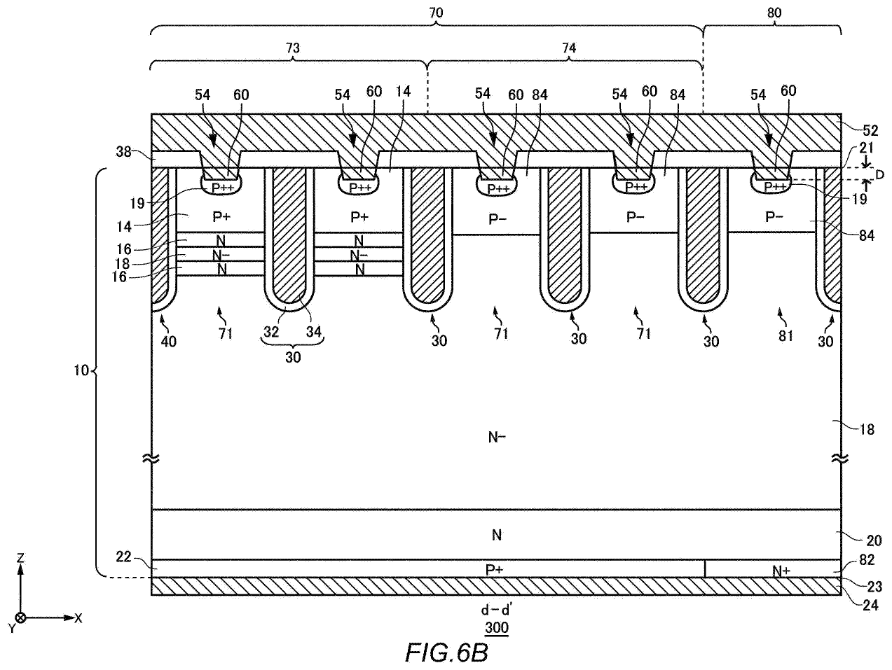

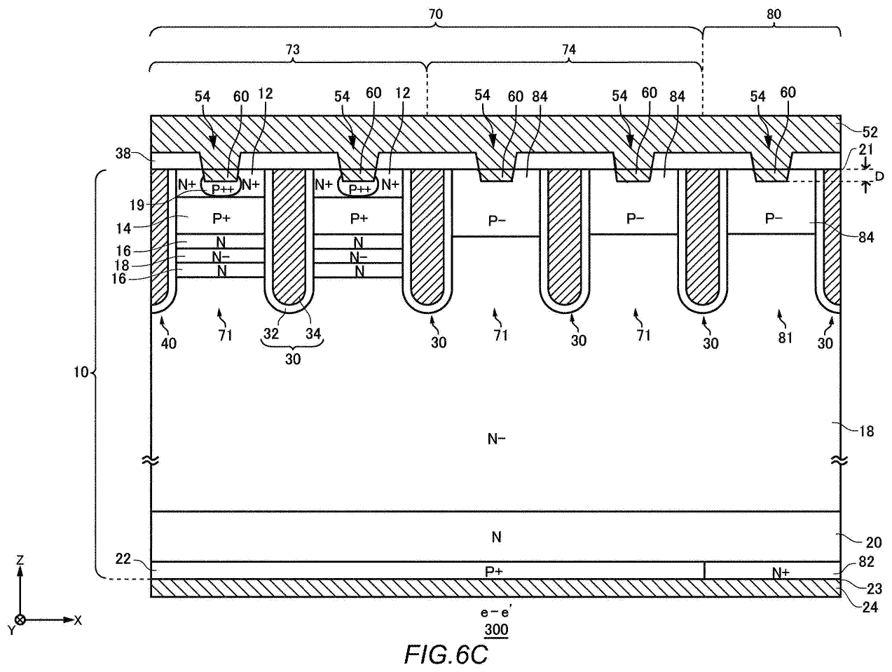

FIG. 6A shows an example of a top plan view of a semiconductor device 300 according to example embodiment 3. Here, an element that is common to FIG. 1A is given the same sign and numeral, and the description thereof will be omitted. In addition, FIG. 6B is a figure showing an example of a cross section d-d′ in FIG. 6A. The cross section d-d′ is an XZ plane passing through the contact region 15, similarly to the cross section b-b′ in FIG. 1C. FIG. 6C is a figure showing an example of a cross section e-e′ in FIG. 6A. The cross section e-e′ is an XZ plane passing through the emitter region 12.

It should be noted that in FIG. 6A, the plug region 19 is highlighted in the diode portion 80 and the second boundary region 74 for a purpose of clarifying the arrangement of the plug region 19. A width of the plug region 19 in the X axis direction may be the same as a width of the contact hole 54 in the X axis direction.

The plug region 19 is selectively provided in the extension direction (the Y axis direction) of the contact hole 54 in the diode portion 80 and the second boundary region 74 of the present example. On the other hand, in the main region 72 and the first boundary region 73, the plug region 19 is provided to cover an entire bottom portion of the contact hole 54.

In this way, by decreasing the area of the plug region 19 in the region where the anode region 84 is provided, it is possible to suppress the hole injection during the reverse recovery. It should be noted that the plug region 19 of the second boundary region 74 may also be selectively provided in the extension direction.

It should be noted that the semiconductor device 300 may not be provided with the plug region 19 in the first boundary region 73 as in FIG. 3A and FIG. 3B. In addition, the semiconductor device 300 may be provided with the accumulation region 86 in the second boundary region 74 and the diode portion 80 as in FIG. 4.

Further, a location where the plug region 19 is selectively provided is not limited to the XZ plane passing through the contact region 15, and may be provided on the XZ plane passing through the emitter region 12, or may be provided on the XZ plane that passes through both of the contact region 15 and the emitter region 12.

In this way, even when the plug region 19 is selectively provided in the extension direction (the Y axis direction) of the contact hole 54 in the diode portion 80 and the second boundary region 74, it is possible to obtain the same effect as in FIG. 1A.

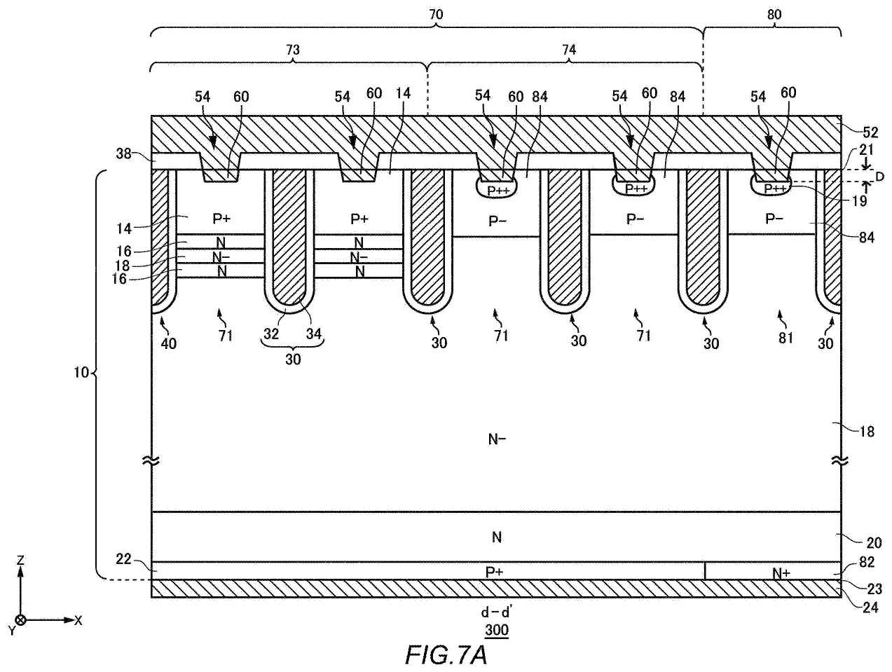

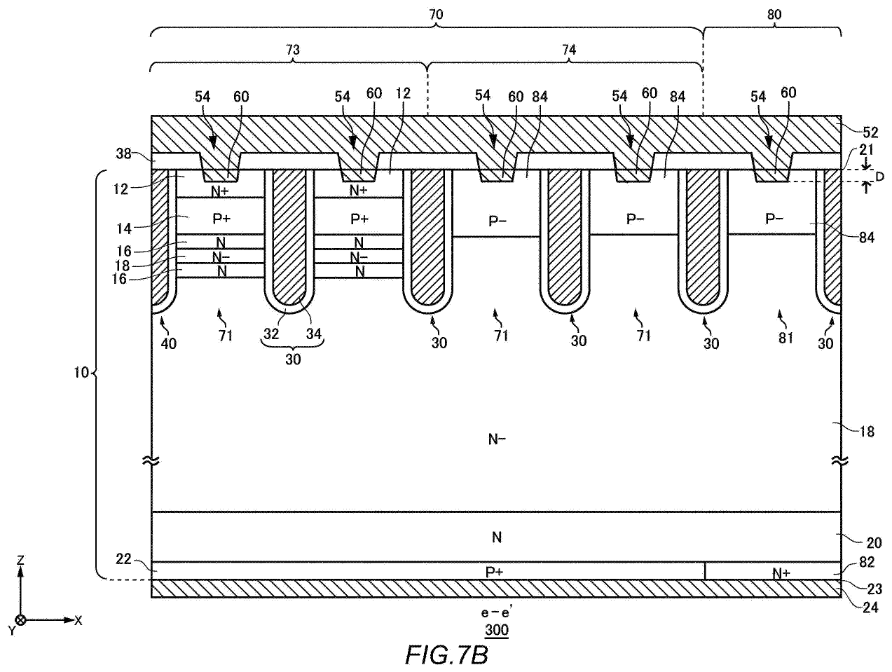

FIG. 7A is a figure showing a modification example of the cross section d-d′ in FIG. 6A. The cross section d-d′ is the XZ plane passing through the contact region 15, similarly to the cross section b-b′ in FIG. 1C. FIG. 7B is a figure showing a modification example of the cross section e-e′ in FIG. 6A. The cross section e-e′ is the XZ plane passing through the emitter region 12.

The plug region 19 is selectively provided in the extension direction (the Y axis direction) of the contact hole 54 in the diode portion 80 and the second boundary region 74 of the present example. The plug region 19 is not provided in the first boundary region 73. It should be noted that in the main region 72 (not shown), the plug region 19 is provided to cover the entire bottom portion of the contact hole 54.

In the present modification example, the plug region 19 is not provided at the lower end of the trench contact portion 60 provided in the first boundary region 73 as in FIG. 3A and FIG. 3B. That is, in the first boundary region 73, the bottom portion and the side wall of the trench contact portion 60 are covered with the emitter region 12 or the base region 14.

In this way, by providing the plug region 19 in a region other than the first boundary region 73 and omitting the plug region 19 in the first boundary region 73, it is possible to further suppress the hole injection during the reverse recovery while the extraction of the hole is facilitated.

In addition, even when the plug region 19 is selectively provided in the extension direction (the Y axis direction) of the contact hole 54 in the diode portion 80 and the second boundary region 74, it is possible to obtain the same effect as in FIG. 1A.

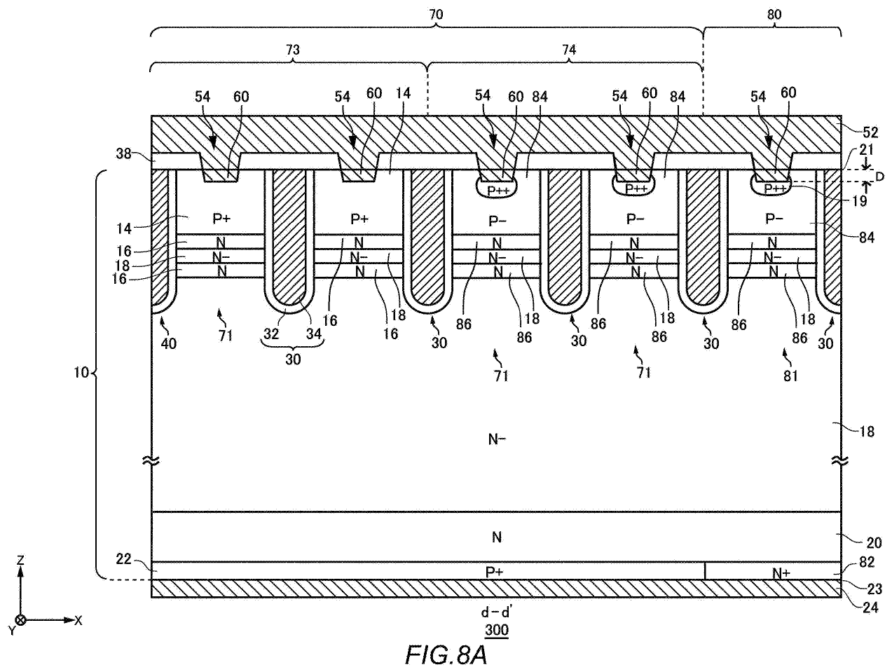

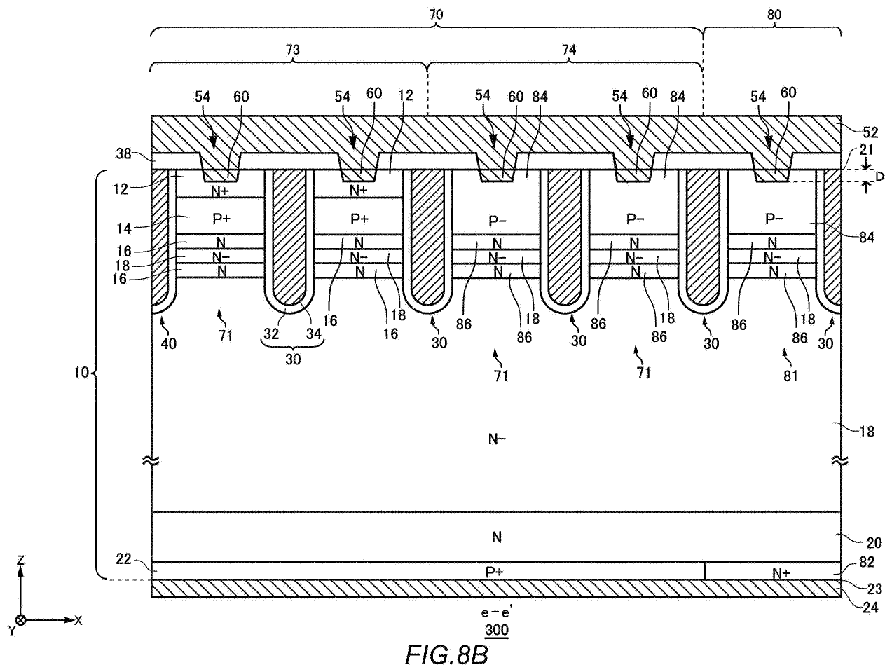

FIG. 8A is a figure showing a modification example of the cross section d-d′ in FIG. 6A. The cross section d-d′ is the XZ plane passing through the contact region 15, similarly to the cross section b-b′ in FIG. 1C. FIG. 8B is a figure showing a modification example of the cross section e-e′ in FIG. 6A. The cross section e-e′ is the XZ plane passing through the emitter region 12.

the present modification example is different from FIG. 7A and FIG. 7B in that the accumulation region 86 of the first conductivity type is provided below the anode region 84 in the second boundary region 74 and the diode portion 80 as in FIG. 4. The accumulation region 86 of the present example is of the same conductivity type as that of the drift region 18, and is of the N type, as an example. Similarly to the accumulation region 16, the accumulation region 86 of two or more stages may be provided in the drift region 18. The doping concentration of the accumulation region 86 is lower than the doping concentration of the accumulation region 16. The doping concentration of the accumulation region 86 may be 1E11 cm⁻³ or more and 1E12 cm⁻³ or less.

As the present modification example, even when the accumulation region 86 of the first conductivity type is provided below the anode region 84 in the second boundary region 74 and the diode portion 80, it is possible to obtain the same effect as in FIG. 7A and FIG. 7B.

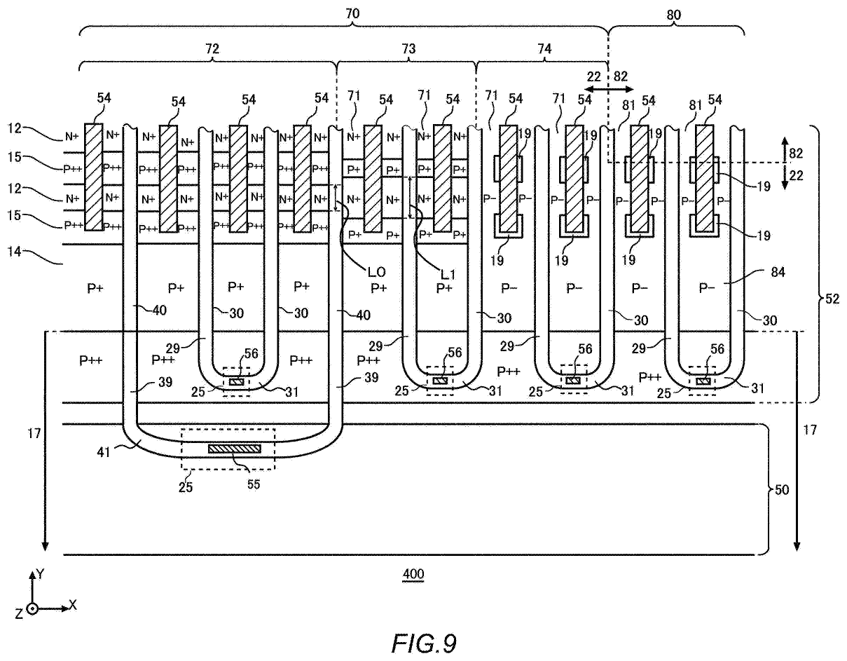

FIG. 9 shows an example of a top plan view of a semiconductor device 400 according to example embodiment 4. Here, an element that is common to FIG. 1A is given the same sign and numeral, and the description thereof will be omitted. It should be noted that in the present example, the plug region 19 is highlighted in the diode portion 80 and the second boundary region 74 for the purpose of clarifying the arrangement of the plug region 19. A width of the plug region 19 in the X axis direction may be the same as a width of the contact hole 54 in the X axis direction.

In the present example, in the top view of the semiconductor substrate 10, a length L0 of the emitter region 12 provided in the main region 72 in the extension direction is larger than a length L1 of the emitter region 12 provided in the first boundary region 73 in the extension direction. In addition, the plug region 19 is selectively provided in the extension direction (the Y axis direction) of the contact hole 54 in the diode portion 80 and the second boundary region 74.

That is, in the present example, in the top view of the semiconductor substrate 10, an area ratio of the emitter region 12 in the first boundary region 73 is greater than an area ratio of the emitter region 12 in the main region 72. In addition, in the top view of the semiconductor substrate 10, an area ratio of the base region 14 in the first boundary region 73 is smaller than an area ratio of the contact region 15 in the main region 72.

In this way, in the first boundary region 73, by increasing the area ratio of the emitter region 12 and decreasing the area ratio of the base region 14, it is possible to further increase the area of the active region and to suppress the hole injection during the reverse recovery.

In addition, by decreasing the area of the plug region 19 in the region where the anode region 84 is provided, it is possible to suppress the hole injection during the reverse recovery.

It should be noted that the semiconductor device 400 may be provided with the plug region 19 in the first boundary region 73 as in FIG. 6B and FIG. 6C, and may not be provided with the plug region 19 in the first boundary region 73 as in FIG. 7A and FIG. 7B.

In addition, the semiconductor device 400 may be provided with the accumulation region 86 in the second boundary region 74 and the diode portion 80.

Further, a location where the plug region 19 is selectively provided is not limited to the XZ plane passing through the contact region 15, and may be provided on the XZ plane passing through the emitter region 12, or may be provided on the XZ plane that passes through both of the contact region 15 and the emitter region 12.

Even when the plug region 19 is selectively provided in the extension direction (the Y axis direction) of the contact hole 54 in the diode portion 80 and the second boundary region 74, it is possible to obtain the same effect as in FIG. 1A.

While the embodiments of the present invention have been described, the technical scope of the present invention is not limited to the above described embodiments. It is apparent to persons skilled in the art that various alterations and improvements can be added to the above described embodiments. It is also apparent from the description of the claims that the embodiments to which such alterations or improvements are made can be included in the technical scope of the present invention.

The operations, procedures, steps, and stages of each process performed by an apparatus, system, program, and method shown in the claims, specification, or drawings can be performed in any order as long as the order is not indicated by “prior to,” “before,” or the like and as long as the output from a previous process is not used in a later process. Even if the process flow is described using phrases such as “first” or “next” in the claims, specification, or drawings, it does not necessarily mean that the process must be performed in this order.

### EXPLANATION OF REFERENCES

10: semiconductor substrate; 12: emitter region; 14: base region; 15: contact region; 16: accumulation region; 17: well region; 18: drift region; 19: plug region; 20: buffer region; 21: front surface; 22: collector region; 23: back surface; 24: collector electrode; 25: connection portion; 29: extension part; 30: dummy trench portion; 31: connection part; 32: dummy dielectric film; 34: dummy conductive portion; 38: interlayer dielectric film; 39: extension part; 40: gate trench portion; 41: connection part; 42: gate dielectric film; 44: gate conductive portion; 50: gate metal layer; 52: emitter electrode; 54: contact hole; 55: contact hole; 56: contact hole; 60: trench contact portion; 70: transistor portion; 71: mesa portion; 72: main region; 73: first boundary region; 74: second boundary region; 80: diode portion; 81: mesa portion; 82: cathode region; 83: second cathode region; 84: anode region; 86: accumulation region; 100: semiconductor device; 173: first boundary region; 174: second boundary region; 200: semiconductor device; 300: semiconductor device; 400: semiconductor device; 1100: semiconductor device.

What is claimed is:

1. A semiconductor device comprising:
a semiconductor substrate that has a transistor portion and a diode portion and that is provided with a plurality of trench portions, wherein
the transistor portion has:
an emitter region of a first conductivity type provided at a front surface of the semiconductor substrate;
a base region of a second conductivity type provided in the semiconductor substrate; and
a contact region of the second conductivity type that is provided at the front surface of the semiconductor substrate and that has a doping concentration higher than that of the base region,
the diode portion has an anode region of the second conductivity type that is provided at the front surface of the semiconductor substrate and that has a doping concentration lower than that of the base region, and
the transistor portion has:
a main region that has the emitter region and the contact region at the front surface of the semiconductor substrate and that is spaced apart from the diode portion; and
a first boundary region that is provided between the main region and the diode portion and that has, at the front surface of the semiconductor substrate, the emitter region and the base region which are alternately provided in a trench extension direction.

2. The semiconductor device according to claim 1, wherein
the main region has, at the front surface of the semiconductor substrate, the contact region and the emitter region alternately which are provided in the trench extension direction.

3. The semiconductor device according to claim 1, wherein
a lifetime control region that includes a lifetime killer is not provided in a front surface side of the semiconductor substrate.

4. The semiconductor device according to claim 1, wherein
the transistor portion has a second boundary region provided between the first boundary region and the diode portion, and
the second boundary region has the anode region at the front surface of the semiconductor substrate.

5. The semiconductor device according to claim 2, wherein
the transistor portion has a second boundary region provided between the first boundary region and the diode portion, and
the second boundary region has the anode region at the front surface of the semiconductor substrate.

6. The semiconductor device according to claim 1, wherein
each of the transistor portion and the diode portion further has a trench contact portion provided at the front surface of the semiconductor substrate, and
a lower end of the trench contact portion is shallower than a lower end of the emitter region.

7. The semiconductor device according to claim 2, wherein
each of the transistor portion and the diode portion further has a trench contact portion provided at the front surface of the semiconductor substrate, and
a lower end of the trench contact portion is shallower than a lower end of the emitter region.

8. The semiconductor device according to claim 1, wherein
each of the transistor portion and the diode portion further has a trench contact portion provided at the front surface of the semiconductor substrate, and
a lower end of the trench contact portion has a same depth as a lower end of the emitter region.

9. The semiconductor device according to claim 2, wherein
each of the transistor portion and the diode portion further has a trench contact portion provided at the front surface of the semiconductor substrate, and
a lower end of the trench contact portion has a same depth as a lower end of the emitter region.

10. The semiconductor device according to claim 6, wherein
each of the transistor portion and the diode portion further has a plug region of the second conductivity type that is provided at a bottom portion of the trench contact portion and that has a doping concentration higher than that of the base region.

11. The semiconductor device according to claim 8, wherein
each of the transistor portion and the diode portion further has a plug region of the second conductivity type that is provided at a bottom portion of the trench contact portion and that has a doping concentration higher than that of the base region.

12. The semiconductor device according to claim 10, wherein
the plug region is not provided in the first boundary region.

13. The semiconductor device according to claim 6, wherein
the transistor portion has a second boundary region provided between the first boundary region and the diode portion,
each of the main region and the first boundary region has a plug region of the second conductivity type that is provided at a bottom portion of the trench contact portion and that has a doping concentration higher than that of the base region, and
each of the diode portion and the second boundary region is selectively provided with the plug region that is provided at the bottom portion of the trench contact portion and that has a doping concentration higher than that of the base region.

14. The semiconductor device according to claim 8, wherein
the transistor portion has a second boundary region provided between the first boundary region and the diode portion,
each of the main region and the first boundary region has a plug region of the second conductivity type that is provided at a bottom portion of the trench contact portion and that has a doping concentration higher than that of the base region, and
each of the diode portion and the second boundary region is selectively provided with the plug region that is provided at the bottom portion of the trench contact portion and that has a doping concentration higher than that of the base region.

15. The semiconductor device according to claim 6, wherein
the transistor portion has a second boundary region provided between the first boundary region and the diode portion,
the main region has a plug region of the second conductivity type that is provided at a bottom portion of the trench contact portion and that has a doping concentration higher than that of the base region, and
each of the diode portion and the second boundary region is selectively provided with the plug region that is provided at the bottom portion of the trench contact portion and that has a doping concentration higher than that of the base region.

16. The semiconductor device according to claim 8, wherein
the transistor portion has a second boundary region provided between the first boundary region and the diode portion,
the main region has a plug region of the second conductivity type that is provided at a bottom portion of the trench contact portion and that has a doping concentration higher than that of the base region, and
each of the diode portion and the second boundary region is selectively provided with the plug region that is provided at the bottom portion of the trench contact portion and that has a doping concentration higher than that of the base region.

17. The semiconductor device according to claim 1, wherein
the transistor portion further has an accumulation region of the first conductivity type provided in the semiconductor substrate.

18. The semiconductor device according to claim 17, wherein
the accumulation region is not provided below the anode region.

19. The semiconductor device according to claim 17, wherein
the accumulation region is provided in both of the transistor portion and the diode portion, and the accumulation region provided below the anode region has a doping concentration lower than that of the accumulation region provided below the base region.

20. The semiconductor device according to claim 1, wherein
the transistor portion further has a collector region of the second conductivity type provided on a back surface of the semiconductor substrate,
the diode portion further has:
a first cathode region of the first conductivity type provided on the back surface of the semiconductor substrate; and
a second cathode region of the second conductivity type that is provided on the back surface of the semiconductor substrate and that has an area smaller than that of the first cathode region.
